(19) United States
(12) Patent Application Publication
(10) Pub. No.: US 2013/0048061 A1
(43) Pub. Date: Feb. 28, 2013

(54) MONOLITHIC MULTI-JUNCTION PHOTOVOLTAIC CELL AND METHOD

(71) Applicants: CHENG-WEI CHENG, White Plains, NY (US); Jack O. Chu, Manhasset Hills, NY (US); Jeehwan Kim, Los Angeles, CA (US); Devendra K. Sadana, Pleasantville, NY (US); Kuen-Ting Shiu, White Plains, NY (US)

(72) Inventors: CHENG-WEI CHENG, White Plains, NY (US); Jack O. Chu, Manhasset Hills, NY (US); Jeehwan Kim, Los Angeles, CA (US); Devendra K. Sadana, Pleasantville, NY (US); Kuen-Ting Shiu, White Plains, NY (US)

(73) Assignee: INTERNATIONAL BUSINESS MACHINES CORPORATION, Armonk, NY (US)

(21) Appl. No.: 13/216,744

(22) Filed: Aug. 24, 2011

(51) Int. Cl. H01L 31/06; H01L 31/18

(52) U.S. Cl. 136/255; 438/94; 257/E31.004

(57) ABSTRACT

A device and method for fabrication of a multi-junction photovoltaic device includes providing a parent substrate including a single crystal III-V material. The parent substrate forms a III-V cell of the multi-junction photovoltaic device. A lattice-matched Germanium layer is epitaxially grown on the III-V material to form a final cell of the multi-junction photovoltaic device. The Germanium layer is bonded to a foreign substrate.

### BACKGROUND

1. Technical Field

The present invention relates to photovoltaic devices, and more particularly to a tandem device having a lattice-matched Ge grown cell.

2. Description of the Related Art

Solar cells employ photovoltaic cells to generate current flow. Photons in sunlight hit a solar cell or panel and are absorbed by semiconducting materials, such as silicon. Electrons gain energy allowing them to flow through the material to produce electricity. Therefore, the solar cell converts the solar energy into a usable amount of electricity. A photon need only have greater energy than that of a band gap to excite an electron from the valence band into the conduction band. Since solar radiation is composed of photons with energies greater than the band gap of silicon, the higher energy photons will be absorbed by the solar cell, with some of the energy (above the band gap) being turned into heat rather than into usable electrical energy.

To take advantage of all available radiation, photovoltaic cells are stacked generally with a top cell having a highest band gap and a bottom cell having a lowest bandgap. The bandgap order along with lattice mismatch concerns between different materials often leads to problems with material selection. It is difficult to find suitable materials with appropriate bandgaps that can be fabricated with compatible lattice constants.

### SUMMARY

A device and method for fabrication of a multi-junction photovoltaic device includes providing a parent substrate including a single crystal III-V material. The parent substrate and/or any subsequently grown III-V epitaxy layers form a multi-junction photovoltaic device. A lattice-matched Germanium layer is epitaxially grown on the III-V material to form a last cell of the multi-junction photovoltaic device. The multi-junction photovoltaic device is bonded to a foreign substrate and detached from the III-V parent substrate.

A method for fabrication of a multi junction photovoltaic device includes providing a parent substrate including a single crystal III-V material, the parent substrate forming a first cell of the multi-junction photovoltaic device; epitaxially growing a lattice-matched Germanium layer on the III-V material to form a second cell of the multi-junction photovoltaic device; and bonding the Germanium layer to a foreign substrate to form the multi-junction photovoltaic device.

Another method for fabrication of a multi-junction photovoltaic device includes providing a handling substrate for forming a stack of photovoltaic cells; growing a first lattice-matched material on the handling substrate to form a cell of the multi-junction photovoltaic device; growing a second lattice-matched material on the first material to form another cell of the multi-junction photovoltaic device, the second material including a single crystal III-V material; epitaxially growing a lattice-matched Germanium layer on the second material to form a last cell of the multi-junction photovoltaic device; and bonding the Germanium layer to a foreign substrate to foam the multi-junction photovoltaic device.

A photovoltaic device includes a parent substrate including a single crystal III-V material, the parent substrate forming a first cell of a multi-junction photovoltaic device. A Germanium layer is epitaxially grown directly on the III-V material and lattice-matched to the parent substrate to form a second cell of the multi-junction photovoltaic device. A foreign substrate is bonded to the Germanium layer.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a multi-junction photovoltaic stack having a Ge layer grown on a III-V layer in accordance with the present principles;

FIG. 2 is a cross-sectional view of the multi-junction photovoltaic stack of FIG. 1 having the Ge layer bonded to a foreign substrate in accordance with the present principles;

FIG. 3 is a cross-sectional view of a multi-junction photovoltaic stack having a Ge layer grown on a stack of at least two other cells and a parent substrate in accordance with another embodiment;

FIG. 4 is a cross-sectional view of the multi-junction photovoltaic stack of FIG. 3 having the Ge layer bonded to a foreign substrate in accordance with the present principles;

FIG. 5 is a cross-sectional view of the multi-junction photovoltaic stack of FIG. 4 having the parent substrate removed in accordance with the present principles; and

FIG. 6 is a block/flow diagram showing a fabrication process for a multi-junction photovoltaic stack in accordance with one illustrative embodiment.

### DETAILED DESCRIPTION OF PREFERRED EMBODIMENTS

In accordance with the present principles, a device and method are provided in which a tandem structure includes a III-V parent substrate, III-V epitaxial grown layers and an epitaxial Ge layer. The Ge layer is lattice matched with the III-V parent substrate and is processed with few, if any, lattice defects.

Conventional structures that employ Germanium (Ge) often start with a Ge parent substrate that is expensive to fabricate. A III-V material may be formed on the Ge parent substrate (usually GaAs). The Ge substrate will be processed to form an n+-layer and a p+-layer. Forming an n+ Ge layer is difficult to achieve. In addition, epitaxially growing a lattice-matched layer on Ge is difficult. The epitaxial interface between Ge and, say, GaAs is prone to anti-phase defects, and atoms interact at the boundary forming undesirable interfacial compounds. Further, Ge diffuses into a GaAs p+ tunnel junction, and, likewise Ga diffuses into a Ge n+ tunnel junction at the interface during processing since growing GaAs on Ge requires high temperatures (e.g., greater than 600 degrees C.). In a triple junction, InGaAs may be used to replace the role of Ge. In this scheme, a graded buffer is needed to reconcile the lattice mismatch between the GaAs and the InGaAs. Nevertheless, the dislocation due to lattice mismatch still cannot be totally eliminated, and therefore will be harmful to the efficiency, reliability, and the lifetime of the resulting tandem solar cells.

The present principles overcome the high material and fabrication expenses for tandem cells that employ a Ge/III-V interface. In one embodiment, a III-V material is employed for both the III-V parent substrate and grown III-V epitaxial layers, and Ge is grown on the III-V material. Growing Ge on the III-V material avoids the formation of anti-phase defects. Further, since Ge is being grown, the Ge can be grown with n-dopants to make it easier and less expensive to form n+ Ge. Further, diffusion is reduced since the formation of Ge can be performed at a low temperature (e.g., less than about 450 degrees C.). By employing the III-V material as the parent substrate, a traditional smart cut process, such as epitaxial lift-off, can be easily employed to make the thin-film tandem solar cell.

It is to be understood that the present invention will be described in terms of a given illustrative architecture having substrates and photovoltaic stacks; however, other architectures, structures, substrates, materials, process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for a photovoltaic device may be created for integrated circuit integration or may be combined with components on a printed circuit board. The circuit/board may be embodied in a graphical computer programming language, and stored in a computer storage medium (such as a disk, tape, physical hard drive, or virtual hard drive such as in a storage access network). If the designer does not fabricate chips or the photolithographic masks used to fabricate chips or photovoltaic devices, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of photovoltaic devices and/or integrated circuit chips with photovoltaic devices. The resulting devices/chips can be distributed by the fabricator in raw wafer form (that is, as a single wafer that has multiple unpackaged devices/chips), as a bare die, or in a packaged form. In the latter case the device/chip is mounted in a single chip package (such as a plastic carrier, with leads that are affixed to a motherboard or other higher level carrier) or in a multichip package (such as a ceramic carrier that has either or both surface interconnections or buried interconnections). In any case, the device/chip are then integrated with other chips, discrete circuit elements, and/or other signal processing devices as part of either (a) an intermediate product, such as a motherboard, or (b) an end product. The end product can be any product that includes integrated circuit chips, ranging from toys, energy collectors, solar devices and other applications including computer products or devices having a display, a keyboard or other input device, and a central processor. The present embodiments may be part of a photovoltaic device or circuit, and the circuits as described herein may be part of a design for an integrated circuit chip, a solar cell, a light sensitive device, etc.

It should also be understood that material compounds will be described in terms of listed elements, e.g., GaInP or InGaAs. These compounds include different proportions of the elements within the compound, e.g., InGaAs includes In_{0.3},Ga_{0.7}As, In_{0.28},Ga_{0.72}As, etc. In addition, other elements may be included in the compound, such as, e.g., AlInGaAs, and still function in accordance with the present principles.

It is also to be understood that the present invention will be described in terms of a given illustrative architecture having a particular tandem (multijunction) structure; however, other architectures, structures, substrate materials and process features and steps may be varied within the scope of the present invention. The tandem structure mainly includes cells, which will be described in terms of a particular material, and the tunneling junctions between cells. While each cell includes a p-doped layer, an n-doped layer and perhaps an undoped intrinsic layer, the n-doped layer and p-doped layers will be omitted from the FIGS. and the description for ease of explanation. Instead, for simplicity, each cell layer will be described in terms of a base layer material (having a band gap associated with the base layer), and the tunnel junctions will be omitted from the FIGS. The n-doped and p-doped regions may be formed by doping during epitaxial growth or doped after formation by any known implantation or diffusion process. Note that in III-V tandem cells, no intrinsic layer is needed in the cell.

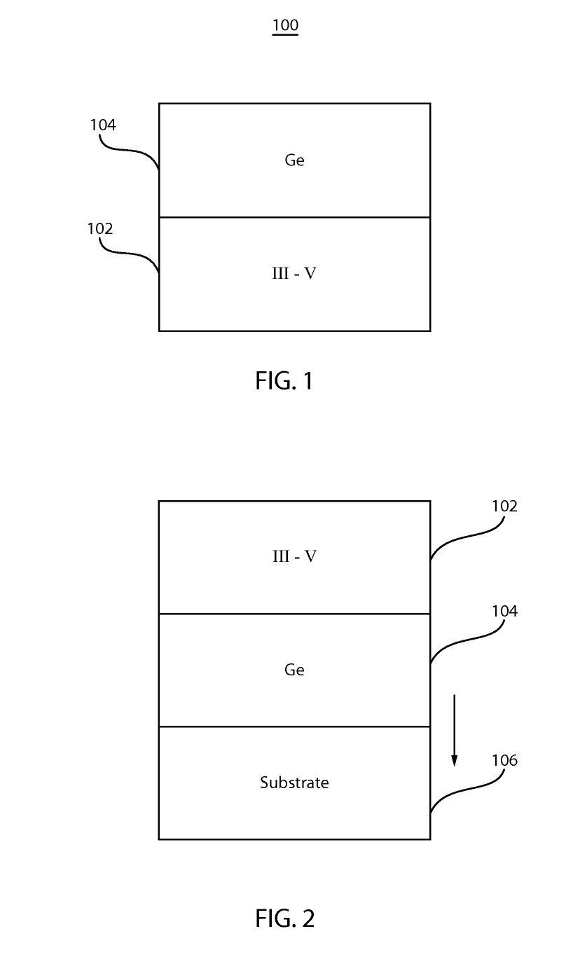

Referring now to the drawings in which like numerals represent the same or similar elements and initially to FIG. 1, an illustrative tandem photovoltaic structure 100 is illustratively depicted in accordance with one embodiment. The photovoltaic structure 100 may be employed in solar cells, light sensors, photosensitive devices or other photovoltaic applications. The embodiment depicted in FIG. 1 includes two cells 102 and 104 stacked in tandem in accordance with one illustrative embodiment. Cell 102 is a III-V cell on which cell 104 is grown. Cell 102 includes III-V material, such as e.g., GaAs, InGaP, AlGaAs, or other suitable material. Cell 104 includes a material that is lattice-matched to the material of cell 102. Cell 104 preferably includes Ge and is grown on the III-V material of cell 102.

By starting with a III-V material in cell 102, cell 104 can be relatively thinner, e.g., 50-1000 nm. If cell 104 is Ge, this results in a significant reduction in material cost over devices employing a Ge parent substrate. In addition, the Ge cell 102 may include an n-type layer, which can be formed while the Ge is being deposited. The n-type dopants are provided in a processing chamber to form an n+ Ge layer at the bottom of cell 104 (not shown). A p+ layer may be formed at a top of the Ge cell 104 during formation by changing the dopant type during the Ge growth process. The n+ layer and the p+ layer are thin layers (e.g., 1-50 nm) formed on the bottom and top of the cell 104, it should be understood that these layers may be reversed (top and bottom) depending on the desired configuration.

In a particularly useful embodiment, Ge cell 104 is formed on a GaAs or other III-V material in cell 102 by employing an ultra-high vacuum chemical vapor deposition process (UHV-CVD), metalorganic chemical vapor deposition (MOCVD) or molecular beam epitaxy (MBE). Pre-processing of the parent substrate (cell 102) may include a removal of a native oxide from the III-V material (e.g., GaAs). In this example, GaAs of cell 102 is prebaked in an ultra-high vacuum (UHV) at a temperature of between about 500 and 650 degrees C. for about 0.1-30 minutes. UHV may be about 10⁻⁷ mTorr for the prebake. The prebake process removes the native oxide by desorption and without causing surface roughness so that Ge for cell 104 can be formed directly on the GaAs. GaAs and Ge are lattice matched and therefore very few defects should be encountered since the GaAs will be smooth (low roughness).

The formation of the Ge layer for cell 104 includes epitaxial growth using one of the UHV-CVD, MOCVD, or MBE processes. For either UHV-CVD or MOCVD, this includes using a GeH₄ process gas at a pressure of about 0.1 mTorr to about 1000 mTorr. The pressure may be adjusted to adjust the rate of formation of the Ge layer for cell 104. For UHV-CVD, MOCVD, or MBE processes, the process temperature is maintained at or below 500 degrees C. This preserves the lattice structure by reducing diffusion between the Ge and the GaAs layers. Anti-phase defects are also avoided. The present process results in better overall performance of the photovoltaic device which is ultimately fabricated.

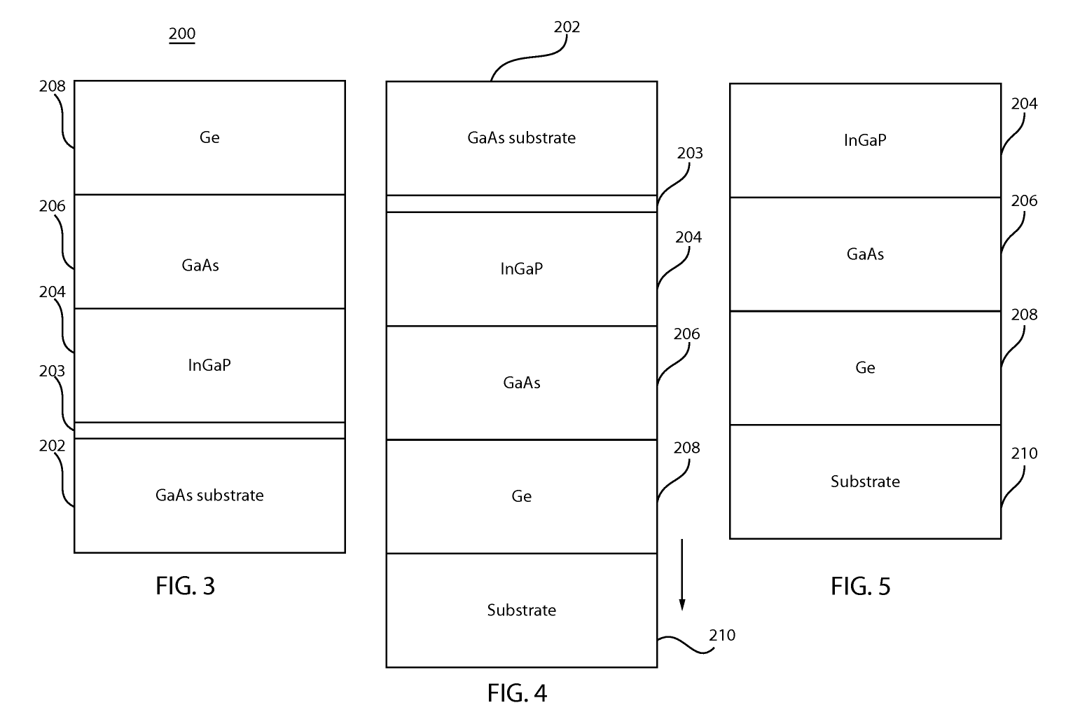

Referring to. FIG. 2, in one embodiment, the device 100 fabricated in FIG. 1 is flipped and transferred to a foreign substrate 106. The foreign substrate 106 may include a transparent material, such as glass or polymeric material or may include a metal or other conductive material depending on the device design and application. Cell 104 is bonded or otherwise adhered to the substrate 106. The bonding process may include any known bonding process where a substrate is joined to the material of cell 104. Note that the process of forming the Ge cell 104 on the III-V cell 102 is reversed from conventional cell fabrication techniques, which begin with a Ge parent substrate (Ge is not grown). While FIGS. 1 and 2 show a double junction tandem cell, large multi-junction cells are contemplated. FIGS. 3, 4 and 5 show an illustrative example of a triple junction photovoltaic device.

Referring to FIG. 3, an illustrative tandem photovoltaic structure 200 is illustratively depicted in accordance with another embodiment. The photovoltaic structure 200 may be employed in solar cells, light sensors, photosensitive devices or other photovoltaic applications. The embodiment depicted in FIG. 3 includes three cells 204, 206 and 208 stacked in tandem in accordance with one illustrative embodiment. In a first stage of the fabrication process, a parent substrate 202 is provided onto which the cells of the structure 200 will be formed. The substrate 202 preferably includes a material which is lattice matched with the other cells to be formed. It should be understood that the material selection for cells 204, 206 and 208 will consider bandgap energy and lattice constants to provide a high efficiency photovoltaic device. In one embodiment, substrate 202 includes GaAs and cell 204 is grown on the substrate 206. The substrate 202 may be subjected to a UHV prebake to clean native oxide from the substrate 206.

Cell 204 includes a material that is lattice-matched to substrate 202. Cell 204 may include, e.g., InGaP, InAlP or InGaAlP. Cell 204 may be formed using MOCVD or MBE. Cell 204 now acts as a parent substrate on which cell 206 is grown. Cell 206 is lattice-matched to cell 204. Cell 206 includes a III-V material, such as e.g., GaAs, AlGaAs, or other suitable material. The GaAs or other material for cell 206 may be formed using a MOCVD or MBE. An UHV prebake is performed on the cell 206 to remove native oxide without contributing to surface roughness (e.g., an in-situ desorption process).

As before, cell 208 is epitaxially grown on cell 206 using one of UHV-CVD, MOCVD or MBE. An UHV prebake is performed on the cell 206 to remove native oxide without contributing to surface roughness (e.g., an in-situ desorption process) before the epitaxial growth of cell 208. Cell 208 includes a material that is lattice-matched to the material of cell 206. Cell 208 preferably includes Ge and is grown on the III-V material of cell 206. Note that each of cells 204, 206 and 208 has respective n-type and p-type layers (not shown) formed on the top and bottom of each of the cells.

Referring to FIG. 4, the stack of cells of device 200 is flipped and transferred to a foreign substrate 210. The substrate 210 may include a transparent material, such as glass or polymeric material or may include a metal or other conductive material depending on the device design and application. Cell 208 is bonded or otherwise adhered to the substrate 210. The bonding process may include any known bonding process where a substrate is joined to the material of cell 208. Note, as before, that the process of forming the Ge cell 208 on the GaAs cell 206 is reversed from conventional cell fabrication techniques.

Referring to FIG. 5, the substrate 202, which facilitates handling of the cell stack, is removed from the cell stack. The substrate 202 may be removed by any known smart-cut process, such as an epitaxial lift-off (ELO) process. Smart-cut, such as an ELO process, includes the separation and manipulation of thin electronic films removed from their substrates. In this case, the substrate 202 is removed from cell 204. ELO relies on the chemical selectivity which manifests itself in epitaxial materials. An interface layer 203 may have been formed on substrate 202. The interface layer 203 is a lattice-matched material to the substrate 202 and the cell 204. The ELO process takes advantage of the high etch selectivity between layer 203 and the adjacent materials. Layer 203 may include e.g., AlAs, or AlGaAs. Once the substrate 202 is employed to handle and transfer the stack to the substrate 210, the substrate 202 is removed by an etching process. The etching process may include a wet etching process, using diluted HF or the like.

By employing the ELO process, cell 204 remains intact and is able to be employed as a photovoltaic cell. The ELO process leaves the remaining materials in pristine condition. While the ELO process is preferred, other processes may be employed to remove substrate 202. For example, a spalling, a polishing process, an etching process, etc. may be employed to remove the substrate 202.

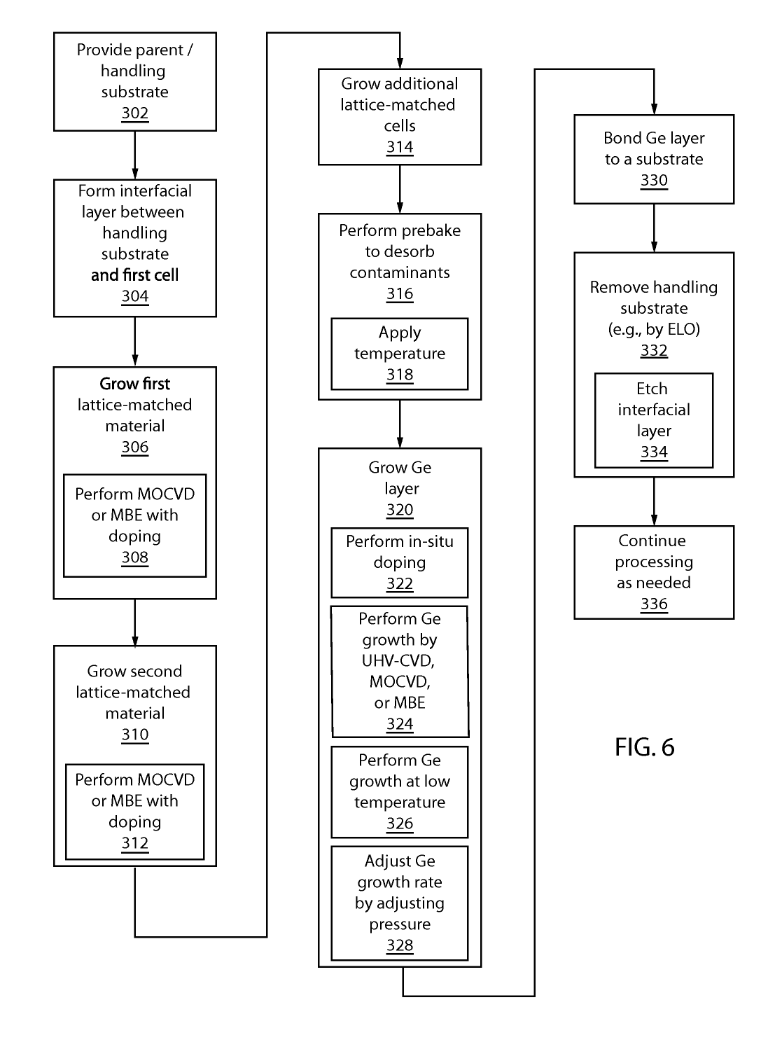

Referring to FIG. 6, a block/flow diagram shows a method for fabricating a tandem cell photovoltaic device in accordance with illustrative embodiments. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

In block 302, a parent or handling substrate may be provided for forming a stack of photovoltaic cells. In block 304, an interfacial layer may be formed between the parent substrate and a first material. These steps are may not be needed depending on the design of the device.

In block 306, a first lattice-matched material is grown on the parent substrate to form a cell of the multi junction photovoltaic device. The first material may include, e.g., InGaP, InAlP, or InGaAlP, and the parent/handling substrate may include GaAs. In block 308, the first lattice-matched material may be grown by performing a metal-organic chemical vapor deposition process, which includes in-situ doping for forming n and p layers.

In block 310, a second lattice-matched material is grown on the first material to form another cell of the multi junction photovoltaic device. The second material preferably includes a single crystal III-V material. The second material may include, e.g., one of GaAs or AlGaAs. In block 312, the first lattice-matched material may be grown by performing metalorganic chemical vapor deposition (MOCVD) or molecular beam epitaxy (MBE).process, which includes in-situ doping for forming n and p layers. It should be rioted that additional cells may be formed as well. In block 314, one or more additional III-V material layers are grown to form additional cells, if desired, for the multi-junction photovoltaic device. These additional layers may also be grown by performing a metalorganic chemical vapor deposition (MOCVD) or molecular beam epitaxy (MBE) process.

In block 316, an ultra-high vacuum prebake may be performed to desorb contaminants from the second material before epitaxially growing the Germanium layer. In block 318, the ultra-high vacuum prebake includes applying a temperature of between about 500 degrees Celsius to about 650 degrees Celsius from between 0.1-30 minutes.

In block 320, a lattice-matched Germanium layer is epitaxially grown on the second material to form a last cell of the multi-junction photovoltaic device. In block 322, in-situ doping is performed for forming n and p layers of the cell.

In block 324, an ultra-high vacuum chemical vapor deposition (UHV-CVD), metalorganic chemical vapor deposition (MOCVD) or molecular beam epitaxy (MBE) process may be performed to grow the Germanium layer. In block 326, the UHV-CVD, MOCVD or MBE process is performed at or below 500 degrees Celsius. In block 328, the UHV-CVD or MOCVD process has a pressure adjusted to control growth rate of the Germanium layer and the pressure is between about 0.1 mTorr and 1000 mTorr.

In block 330, the Germanium layer is bonded to a foreign substrate (e.g., a transparent material) to form the multi-junction photovoltaic device. In block 332, the handling substrate is preferably removed by an epitaxial lift-off (ELO) process. The interfacial layer between the handling substrate and the first material is etched away to remove the handling substrate in block 334. In block 336, processing can continue to complete further features of the device. The device advantageously includes a multi-junction monolithic device with single crystal cells appropriately doped during the fabrication process.

Having described preferred embodiments for monolithic tandem photovoltaic cells and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method for fabrication of a multi junction photovoltaic device, comprising:
providing a parent substrate including a single crystal III-V material, the parent substrate forming a first cell of the multi junction photovoltaic device;
epitaxially growing a lattice-matched Germanium layer on the III-V material to foam a second cell of the multi junction photovoltaic device; and
bonding the Germanium layer to a foreign substrate to form the multi-junction photovoltaic device.

2. The method as recited in claim 1, wherein the parent substrate includes one of GaAs or AlGaAs.

3. The method as recited in claim 1, wherein epitaxially growing includes performing an ultra-high vacuum chemical vapor deposition (UHV-CVD), metalorganic chemical vapor deposition (MOCVD) or molecular beam epitaxy (MBE) process to grow the Germanium layer.

4. The method as recited in claim 3, wherein the UHV-CVD or MOCVD process is performed at or below 500 degrees Celsius.

5. The method as recited in claim 3, wherein the UHV-CVD or MOCVD process has a pressure adjusted to control growth rate of the Germanium layer and the pressure is between about 0.1 mTorr and 1000 mTorr.

6. The method as recited in claim 1, further comprising performing an ultra-high vacuum prebake to desorb contaminants from the parent substrate before epitaxially growing the Germanium layer.

7. The method as recited in claim 6, wherein performing an ultra-high vacuum prebake includes applying a temperature of between about 500 degrees Celsius to about 650 degrees Celsius.

8. A method for fabrication of a multi-junction photovoltaic device, comprising:
providing a handling substrate for forming a stack of photovoltaic cells;
growing a first lattice-matched material on the handling substrate to form a cell of the multi junction photovoltaic device;
growing a second lattice-matched material on the first material to form another cell of the multi-junction photovoltaic device, the second material including a single crystal III-V material;
epitaxially growing a lattice-matched Germanium layer on the second material to form a last cell of the multi-junction photovoltaic device; and
bonding the Germanium layer to a foreign substrate to form the multi-junction photovoltaic device.

9. The method as recited in claim 8, wherein the second material includes one of GaAs or AlGaAs.

10. The method as recited in claim 8, wherein the first material includes one of InGaP, InAlP or InGaAlP.

11. The method as recited in claim 8, wherein epitaxially growing includes performing an ultra-high vacuum chemical vapor deposition (UHV-CVD), metalorganic chemical vapor deposition (MOCVD) or molecular beam epitaxy (MBE) process to grow the Germanium layer.

12. The method as recited in claim 11, wherein the UHV-CVD or MOCVD process is performed at or below 500 degrees Celsius.

13. The method as recited in claim 11, wherein the UHV-CVD or MOCVD process has a pressure adjusted to control growth rate of the Germanium layer and the pressure is between about 0.1 mTorr and 1000 mTorr.

14. The method as recited in claim 8, further comprising performing an ultra-high vacuum prebake to desorb contaminants from the second material before epitaxially growing the Germanium layer.

15. The method as recited in claim 14, wherein performing an ultra-high vacuum prebake includes applying a temperature of between about 500 degrees Celsius to about 650 degrees Celsius.

16. The method as recited in claim 8, further comprising growing one or more additional III-V material layers to form the multi-junction photovoltaic device;

17. The method as recited in claim 8, further comprising removing the handling substrate by an epitaxial lift-off process.

18. The method as recited in claim 17, further comprising forming an interfacial layer between the handling substrate and the first material wherein removing the handling substrate by the epitaxial lift-off process includes etching away the interfacial layer.

19. The method as recited in claim 8, wherein growing a first lattice-matched material includes performing a metal-organic chemical vapor deposition process, or molecular beam epitaxy (MBE).

20. The method as recited in claim 8, wherein growing a second lattice-matched material includes performing a metal-organic chemical vapor deposition, or molecular beam epitaxy (MBE) process.

21. A photovoltaic device, comprising:
a parent substrate including a single crystal III-V material, the parent substrate forming a first cell of a multi-junction photovoltaic device;
a Germanium layer epitaxially grown directly on the III-V material and lattice-matched to the parent substrate to form a second cell of the multi-junction photovoltaic device; and
a foreign substrate bonded to the Germanium layer to form the multi-junction photovoltaic device.

22. The device as recited in claim 21, wherein the parent substrate includes one of GaAs or AlGaAs.

23. The device as recited in claim 21, wherein the Germanium layer has a thickness of less than 5000 nm.

24. The device as recited in claim 21, wherein a surface of the parent substrate is desorbed of contaminants from the parent substrate before the Germanium layer is grown.

25. The device as recited in claim 21, wherein the multi-junction device includes a monolithic triple junction device.
